(19) United States
(12) Patent Application Publication
(10) Pub. No.: US 2007/0010086 A1
(43) Pub. Date: Jan. 11, 2007

(54) Circuit board with a through hole wire and manufacturing method thereof

(75) Inventor: Shih-Chung Hsieh, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/357,987

(22) Filed: Feb. 22, 2006

(30) Foreign Application Priority Data
Jul. 6, 2005 (TW) 94122789

(51) Int. Cl. H01L 21/4763; H05K 1/11; H05K 3/10; H01L 21/44

(52) U.S. Cl. 438/622; 29/846; 29/852; 174/262; 174/261; 438/666; 438/667

(57) ABSTRACT

An aluminum substrate is drilled to form a first through hole, and is then laminated with copper foils on upper and lower surfaces of the aluminum substrate via a binder. Due to the pressure of the lamination, the binder is partially forced to flow into and fill the first through hole, and the binder is then solidified. Concentric with the first through hole, a second through hole having a smaller aperture than the first through hole is drilled. By a non-electrical and electrical plating method, a copper conductive layer is formed on the side wall of the second through hole to complete the through hole wire. Because of the isolation effect of the binder, the aluminum substrate is not electrically connected to the copper foils and the copper conductive layer.

### BACKGROUND OF THE INVENTION

1. Field of the Invention

The invention relates to a circuit board containing aluminum material and a manufacturing method thereof, and in particular, to a circuit board and manufacturing method thereof applied for surface mount device (SMD) module.

2. Description of the Related Art

Usually in an electronic device, there are various electronic components connected to each other on a printed circuit board, and thus the printed circuit board is called “the mother of the electronic system” or “the foundation of the 3C industry”. As a result, the quality of electronic products greatly depends on the quality of the printed circuit board.

A substrate of the printed circuit board, which is mainly composed of compound materials of macromolecular compounds (resin), glass fiber, and high purity copper foils, is also called copper foil substrate. FIG. 1 is a cross-sectional view of a conventional copper foil substrate. The conventional copper foil substrate 1 is mainly composed of a substrate 10 and copper foils 12 attached on upper and lower surfaces of the substrate 10. The substrate 10 and the copper foils 12 are bonded together by a glue or binder 13 therebetween, wherein the substrate 10 is composed of resins and glass fiber.

Phenolic, epoxy, polyimide and PTFE are often used to form the substrate 10. Raw material of glass fiber is mainly made of calcium oxide, aluminum oxide, silicon oxide, and boron oxide, which is similar to common glass, but ductility and insulation are more important than common glass.

Referring to FIG. 2, in practice of connecting circuits on the upper and lower surfaces of the copper foil substrate 1, a through hole 14 has to be formed in the copper foil substrate 1 by drilling in advance. After that, a wall of the through hole 14 is plated with a copper conductive layer 16 by chemical and electrical plating to electrically connect the circuits on the upper and the lower surfaces of the copper foil substrate 1.

Nowadays, electrical equipments are requested to be light-weight and miniaturized, and thus surface mount technology (SMT) has risen to form miniaturized electrical components with great reliability. Surface mount technology (SMT) is a technique of assembling the electronic components on a printed circuit board. With such technology, a SMD module can be accurately disposed, by an SMT chip mounter, on the printed circuit board by solder paste or glue. Then the printed circuit board passes through a wind furnace to complete soldering process. Comparing SMT with dual in-line package (DIP) technology, SMT is easier to assemble electronic components on the printed circuit board; furthermore, electrical components and circuit boards can be miniaturized. Thus, SMT is suitable to meet the requirements of present electrical equipments, and is often applied in electronics and telecommunication, communication systems, aerospace, and electric appliances.

The substrate, which is used in manufacturing an SMD module, mostly uses Flame Resistant 4 (FR4) material as the substrate, and the upper and lower surfaces of the substrate are densely covered with copper circuits. However, this type of substrate cannot effectively solve heat dissipation problems for some components (for example, power amplifier module) which generate excessive heat because the material of the substrate of the conventional substrate is not provided with adequate thermal conductivity. On the other hand, aluminum, with higher thermal conductivity, is often used as a material in heat dissipation components. However, when aluminum is used as the material of the substrate of SMD module, the through hole conductive layer to connect the upper and lower layers of the substrate will be in contact with the aluminum substrate and short circuits will occur.

Solving the heat dissipation problems of the substrate of a SMD module is the main purpose of the invention. The inventor knows the drawbacks of conventional techniques and does his best to complete the invention to solve the conventional problems. A description of the invention is given in the following.

### BRIEF SUMMARY OF THE INVENTION

The invention provides a circuit board with a substrate of a SMD module, wherein the substrate comprises an aluminum substrate with high thermal conductivity to solve heat dissipation problems.

The invention also provides a circuit board manufacturing method. First, at least one first through hole is drilled in an aluminum substrate. Secondly, the aluminum substrate is laminated with at least one copper foil by a binder which is then forced to flow into and fill the first through hole. Thereafter, at least one second through hole is drilled in the first through hole filled with the binder. At last, a copper conductive layer is formed on a side wall of the second through hole by conventional techniques of non-electrical plating and electrical plating.

To achieve the purpose described above, the invention provides an aluminum substrate and a first through hole drilled through the aluminum substrate, wherein the aperture of the first through hole is larger than a predetermined aperture. Next, the upper and lower surfaces of the aluminum substrate are respectively laminated with a copper foil. A binder is used to attach the copper foils and the aluminum substrate for lamination. With the pressure of lamination, the excessive binder is forced to flow into and fills the first through hole, and then is solidified. After, a second through hole with a predetermined aperture is drilled through the first through hole filled with the binder. Lastly, a copper conductive layer is formed on the side wall of the second through hole by non-electrical plating and electrical plating. By the insulation of the binder, the aluminum substrate are unable to connect electrically with the copper foils on the upper and lower surfaces of the aluminum substrate and the copper conductive layer formed on the side wall of the second through hole.

With high thermal conductivity of metal, the invention applies aluminum as the material of the substrate of the SMD module, and provides different drilling and laminating methods, compared to conventional manufacturing methods, to avoid electrical connection among the metal substrate, the upper and lower copper foils, and the copper conductive layer, so as to produce a SMD module with high heat dissipation capacity.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a cross-sectional view of a conventional copper foil substrate;

FIG. 2 is a cross-sectional view of a conventional copper foil substrate with a through hole;

FIG. 3 is a flowchart of an embodiment of a manufacturing method according to the present invention;

FIG. 4 is a 3-D schematic view of an embodiment of a circuit board with a substrate according to the present invention; and

FIG. 5 is a cross-sectional view of FIG. 4.

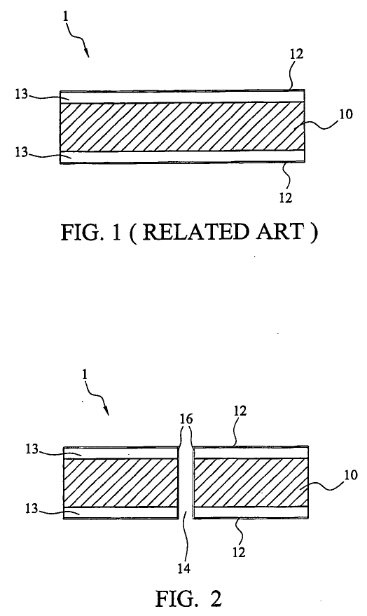

### DETAILED DESCRIPTION OF THE INVENTION

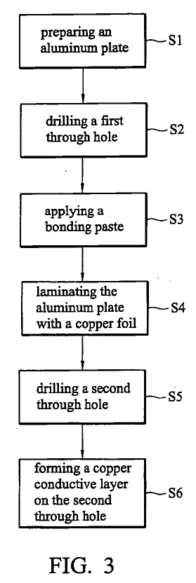

Referring to FIG. 3, FIG. 3 is a flowchart of an embodiment of a manufacturing method for a circuit board of SMD module.

In step S1, an aluminum substrate with a predetermined size is prepared.

In step S2, at least one first through hole is drilled in a predetermined position of the aluminum substrate.

In step S3, a binder is applied on upper and lower surfaces of the aluminum substrate.

In step S4, the upper and lower surfaces of the aluminum substrate are respectively laminated with copper foils so that the binder flows and the first through hole is filled with the binder; thereafter, the binder is solidified.

In step S5, by concentric with the first through hole, at least one second through hole is drilled at a predetermined size within the filled first through hole.

In step S6, a copper conductive layer is formed on an inner side wall of the second through hole by non-electrical plating and electrical plating.

In steps S2 and S5, the position and the number of the first through hole and the second through hole on the aluminum substrate are in predetermined arrangements when the circuit is designed. The aperture of the drilled first through hole in the step S2 is larger than that of the drilled second through hole in the step S5. However, the size of the aperture is not limited and is determined according to requirements. For example, when the aperture of the second through hole is 10 mil in step S6, the aperture of the first through hole can be 30 mil in step S2.

The binder used in steps S3 and S4 is an electrically insulating binder, preferably, an epoxy. The binder is forced to flow into the first through hole and fill the first through hole.

Because non-electrical plating, electrical plating and the techniques of manufacturing a circuit in the following steps are conventional techniques known in related art and are not the main purpose of the invention, the detailed descriptions of these conventional techniques are not described herein. Briefly, the circuits of the upper and lower surfaces of the circuit board are completed according to the predetermined arrangements.

As described above, although the aluminum substrate is a conductor, the binder can be an insulator to separate the aluminum substrate apart the copper conductive layer in the side wall of the through hole and the copper foils on the upper and lower surfaces of the aluminum substrate to avoid short circuits.

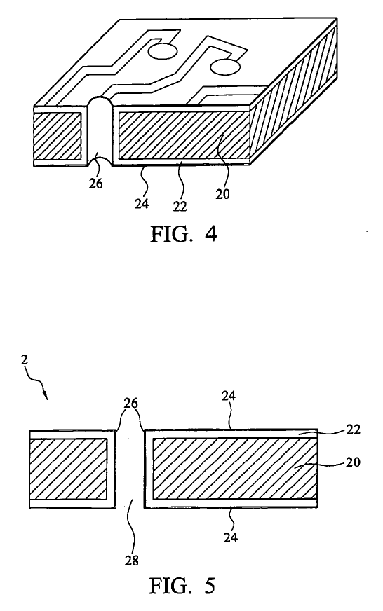

Referring to FIG. 4 and FIG. 5, the structure of the circuit board 2, which is completed by the invention, mainly comprises an aluminum substrate 20, an insulator 22, at least one copper foil 24, and at least one copper conductive layer 26.

The aluminum substrate 20 comprises at least one through hole 28 passing through the upper and lower surfaces of the aluminum substrate 20. The insulator 22 covers the upper and lower surfaces of the aluminum substrate 20 and the side wall of the through hole 28. The copper foils are attached on the upper and lower surfaces of the aluminum substrate 20 via the insulator 22. The copper conductive layer 26 is formed on the surface of the insulator 22, wherein the insulator 22 covers on the side wall of the through hole 28.

The insulator 22 is formed by the solidified binder as described above, which can separate the aluminum substrate 20 apart the copper conductive layer 26 on the side wall of the through hole 28, so that the aluminum substrate 20 and the through hole 28 are unable to connect electrically to cause a short circuit. Additionally, the insulator 22 is also a medium for attaching the at least one copper foil 24 and the aluminum substrate 20 and, is to separate the aluminum substrate 20 apart the at least one copper foil 24 to avoid electrical connection.

Using an aluminum material as the substrate for the SMD module can improve heat dissipation efficiency of the SMD module. Furthermore, the manufacturing method is suitable for complex circuit designs to connect the upper and the lower circuits by the conductive layer of the through hole. Thus, the double-sided SMD module can be achieved.

The invention is particularly suitable for electrical elements which generate a great amount of heat, for example, power amplifier modules. The conventional substrate cannot efficiently dissipate a great amount of heat generated by the power amplifier module. On the contrary, with the circuit board structure and the method of connecting double-sided circuits of the present invention, a pad on the substrate disposed at the bottom layer of the power amplifier module can be soldered on the printed circuit board, and; the upper surface and lower surface circuits of the substrate can be electrically connected via a conductive layer in the through hole without short circuits. Further, heat generated by the power amplifier module can be dissipated rapidly via the aluminum substrate of the substrate.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of manufacturing a circuit board comprising the steps of:
providing an aluminum substrate;
forming at least one first through hole in the aluminum substrate;
applying a binder on at least one surface of the aluminum substrate;
pressurizing at least one copper foil on the surface of the aluminum substrate so that the binder flows and fills the first through hole and is then solidified;
forming at least one second through hole in the first through hole filled with the binder; and
forming at least one copper conductive layer on a side wall of the second through hole.

2. The method as claimed in claim 1, wherein the binder is applied on upper and lower surfaces of the aluminum substrate.

3. The method as claimed in claim 2, wherein the copper foils are respectively laminated on the upper and lower surfaces of the aluminum substrate.

4. The method as claimed in claim 1, wherein an aperture of the first through hole is relatively larger than that of the second through hole.

5. The method as claimed in claim 1, wherein the first through hole and the second through hole are concentric.

6. The method as claimed in claim 1, wherein the binder is an epoxy resin.

7. The method as claimed in claim 1, wherein the copper conductive layer is formed by non-electrical and electrical copper plating.

8. A circuit board comprising:
an aluminum substrate comprising at least one through hole;
an insulator covering a surface of the aluminum substrate and a side wall of the through hole; and
a copper part covering a surface of the insulator;
wherein the aluminum substrate and the copper part are separated by the insulator.

9. The circuit board as claimed in claim 8, wherein the copper part comprises:
at least one copper foil, adhered to the upper or lower surfaces of the aluminum substrate by the insulator; and
at least one copper conductive layer, formed on the surface of the insulator on the side wall of the through hole.

10. The circuit board as claimed in claim 9, wherein the copper conductive layer is formed by non-electrical and electrical copper plating.

11. The circuit board as claimed in claim 8, wherein the material of the insulator is an epoxy resin.

12. The circuit board as claimed in claim 8, wherein the insulator is formed by solidifying a binder.
